(19) United States
(12) Patent Application Publication
(10) Pub. No.: US 2026/0190662 A1
(43) Pub. Date: Jul. 2, 2026

(54) DISPLAY APPARATUS

(71) Applicant: LG Display Co., Ltd., Seoul (KR)

(72) Inventors: So-Ryeong PARK, Paju-si (KR); Do-Hyun KIM, Paju-si (KR)

(73) Assignee: LG Display Co., Ltd., Seoul (KR)

(21) Appl. No.: 19/359,301

(22) Filed: Oct. 15, 2025

(30) Foreign Application Priority Data
Dec. 27, 2024 (KR) 10-2024-0198531

(51) Int. Cl. H10K 59/124; H10K 59/80

(52) U.S. Cl. CPC H10K 59/124; H10K 59/873

(57) ABSTRACT

A display apparatus according to the present disclosure includes a substrate having a display area with a plurality of sub pixels and a non-display area adjacent to the display area. A transistor and a light emitting device are disposed respectively in each sub pixel. The substrate includes a plurality of base layers with at least one intermediate layer positioned between them. A pattern unit is formed in the intermediate layer so that the base layers above and below the intermediate layer directly contact each other through the pattern unit. The pattern unit may include through holes or slits of varying size or density to enhance bonding strength, prevent separation of the layers, and improve flexibility in regions subject to bending, folding, or external stress. This configuration allows reliable mechanical performance while supporting high quality display operation, including applications in foldable or rollable display devices.

### CROSS-REFERENCE TO RELATED APPLICATIONS

This application claims priority to Korean Patent Application No. 10-2024-0198531, filed in the Republic of Korea on December 24, 2027, the entire contents of which is hereby expressly incorporated by reference into the present application.

### BACKGROUND

### Technical Field

A present disclosure related to a display apparatus having improved attaching strength of a plastic substrate.

### Description of the Related Art

Recently, with the development of multimedia, the importance of flat panel display apparatus is increasing. In response, flat panel display apparatus such as liquid crystal display apparatus, plasma display apparatus, and organic light emitting display apparatus are being commercialized. Among these flat panel display apparatuses, the organic light emitting display apparatus is currently widely used because it has a high response speed, high brightness, and good viewing angles.

### BRIEF SUMMARY

In the related art, various flexible display apparatuses have been developed recently. A flexible display apparatus may use a flexible plastic material as a substrate. The plastic substrate may include a first plastic substrate, a second plastic substrate, and an inorganic layer therebetween to prevent moisture from penetrating into the substrate from the outside. However, the plastic substrate having this structure has a problem in that the plastic substrate and the inorganic layer may separate due to the interface characteristics between the inorganic layer and the plastic material. Various embodiments of the present disclosure address the technical problems in the related art, including the problem identified above.

Specifically, the disclosure focuses on improving the structural integrity and flexibility of display apparatus substrates by introducing a patterned intermediate layer between multiple plastic base layers. Through holes or slits are strategically formed in the intermediate inorganic layer so that the upper and lower plastic layers directly contact each other, which enhances bonding strength and prevents delamination during manufacturing, bending, folding, or impact.

One aspect of the disclosure relates to the stress dependent design of these through holes. Their size or density varies according to the stress distribution on the substrate, with larger or denser holes used in regions of higher stress such as edges or folding areas, while areas subject to less stress use smaller or fewer holes. In areas of extreme deformation such as hinges, the intermediate layer can be removed entirely or the holes increased in size, improving flexibility while maintaining structural reliability and preventing crack propagation.

The approach is compatible with active display regions where transistors and light emitting devices are located, allowing robust foldable or rollable displays without affecting performance. Additional encapsulation layers and protective dams further block moisture and oxygen ingress, improving durability.

Various embodiments of the present disclosure provide a display apparatus capable of preventing delamination of a substrate.

For example, a display apparatus according to the present disclosure comprises a substrate including a display area having a plurality of sub pixels and a non-display area outside the display area, and a transistor and a light emitting device disposed respectively in each of the plurality of sub pixels, wherein the substrate includes a plurality of base layers and at least one intermediate layer therebetween, and wherein a pattern unit is formed in the intermediate layer to contact directly the base layers disposed above and below the intermediate layer.

The base layer can be formed of a plastic material and the intermediate layer is formed of an inorganic material. The pattern unit includes a plurality of through holes formed in the intermediate layer and the through hole can be formed in a circular shape or a polygon shape. An area of the through hole can be increased as goes toward an outside of the non-display area and a density of the through hole can be increased as goes toward an outside of the non-display area.

The through hole can be formed in a slit shape, and a width or a length of the through hole is increased as goes toward an outside of the non-display area.

A deformation area can be formed in the non-display area of the substrate, the deformation area can include a bending area, a folding area, a stretching area, and a curved area. The intermediate layer in the deformation area can be deleted and the size of the through hole formed in the intermediate layer of the deformation area can be larger than that in other area.

### BRIEF DESCRIPTION OF THE SEVERAL VIEWS OF THE DRAWINGS

FIG. 1 is a schematic block diagram of a display apparatus according to the present disclosure.

FIG. 2 is the schematic block diagram of a sub pixel according to the present disclosure.

FIG. 3 is a circuit diagram conceptually illustrating the sub pixel of an organic light emitting display apparatus according to the present disclosure.

FIG. 4 is a plan view of the display apparatus according to a first embodiment of the present disclosure.

FIG. 5 is a sectional view of the display apparatus according to the first embodiment of the present disclosure.

FIGS. 6A to 6D are views each showing shape of contact hole of the display apparatus according to a first embodiment of the present disclosure.

FIGS. 7A and 7B are views each showing other shape of contact hole of the display apparatus according to a first embodiment of the present disclosure.

FIG. 8 is the plan view schematically showing the display apparatus according to a second embodiment of the present disclosure.

FIG. 9 is the cross-sectional view taken along line II-II′ of FIG. 8.

FIG. 10 is a view showing other structure of the substrate of the display apparatus according to a second embodiment of the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements are not limited by the terms. When it is described that a component is “connected” “coupled” or “connected” to another component, the component may be directly connected or connected to the other component, but indirectly without specifically stated It should be understood that other components may be “interposed” between each component that is connected or can be connected.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the present disclosure will be described in detail with reference to the accompanying drawings.

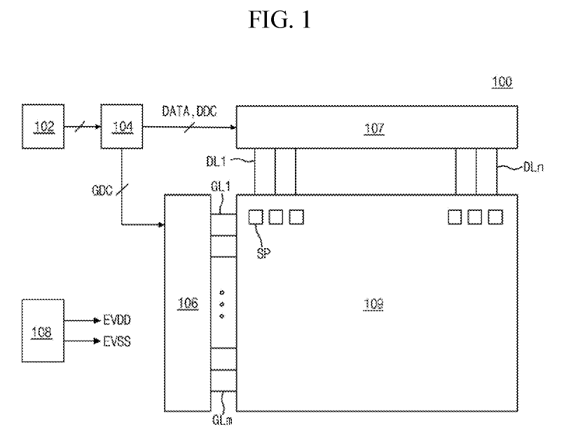

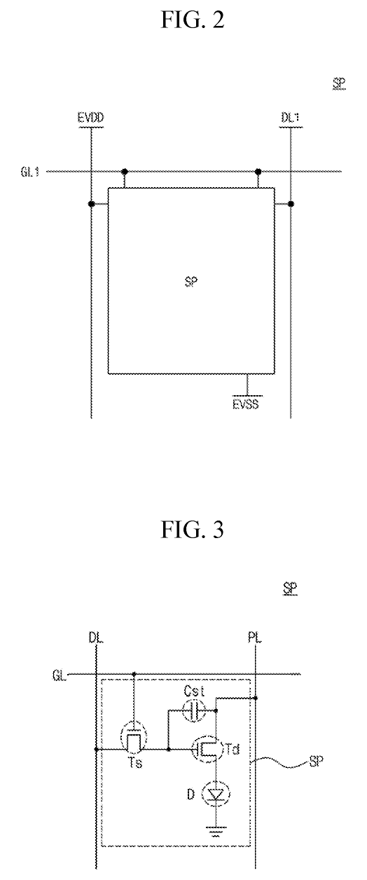

FIG. 1 is the schematic block diagram and FIG. 2 is the schematic block diagram of the sub-pixel of the organic light emitting display apparatus according to the present disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driving unit 106 includes various gate driving circuits, and the gate driving circuit can be formed directly on the substrate of the display panel 109. In this case, the gate driving unit 106 can be a GIP (Gate-In-Panel).

The data driver 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving 107 may be mounted on the upper surface of the display panel 109 in the form of an integrated circuit (IC), but is limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel 109 includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include composed of two transistors and one capacitor (2T1C), but is not limited thereto, and the sub-pixel SP may be composed of 3T1C, 4T1C, 5T1C, 6T1C, 7T1C, 3T2C, 4T2C, 5T2C, 6T2C, 7T2, 8T2C, etc.

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the organic light emitting device D from the power line PL through the driving thin film transistor Td and then the organic light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

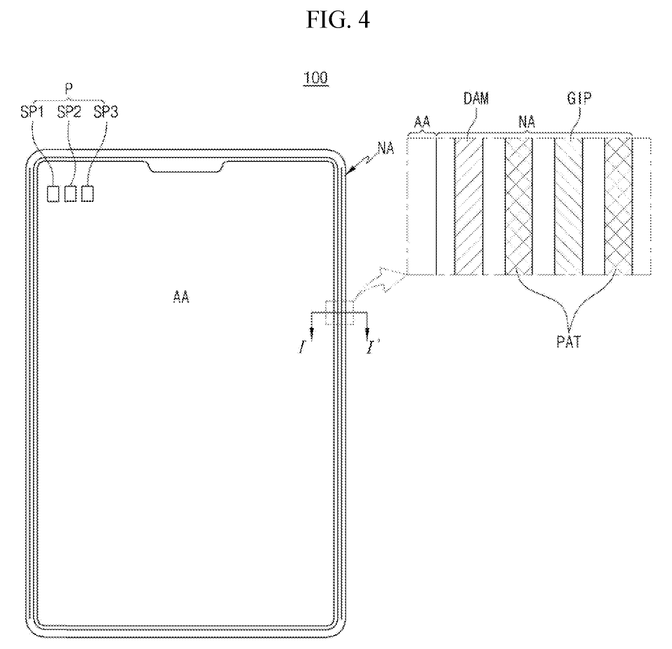

FIG. 4 is a plan view schematically showing the structure of the display apparatus 100 according to the present disclosure.

As shown in FIG. 4, the display apparatus 100 according to the present disclosure includes a display area AA where an actual image is displayed and a non-display area NA outside the display area AA.

A pixel P including a plurality of sub-pixels SP1, SP2, and SP3 is arranged in the display area AA. At this time, each of the sub-pixels SP1, SP2, and SP3 may include a red (R) sub-pixel, a green (G) sub-pixel, and a blue (B) sub-pixel. In addition, the pixel P may further include a white (W) sub-pixel.

Although not shown in the figure, a plurality of gate lines and data lines are arranged in the display area AA to define a plurality of sub-pixels SP in the intersection area of the gate lines and data lines. In each sub-pixel SP1, SP2, and SP3, a thin film transistor as a switching device and a display device for displaying an image are arranged.

The display device may include various display devices. For example, the display device may be an organic light emitting display device, a liquid crystal display device, a quantum dot display device, a micro LED display device, or a mini LED display device.

The gate driving unit 106 and the data driving unit 107 for supplying various signals to sub-pixels SP1, SP2, and SP3 can be disposed in the non-display area NA. The gate driving unit 106 applies the scan signal to the sub-pixels SP1, SP2, and SP3 through the gate line, and the data driving unit 107 applies the image signal to the sub-pixels SP1, SP2, and SP3 through the data line. At this time, the gate driving unit is a Gate-In-Panel that includes gate driving circuits.

The gate driving unit 106 may be disposed in the non-display area NA in both sides of the display area AA, or may be disposed only in the non-display area NA in one side of the display area AA. Further, the gate driving unit 106 may be formed only in one area of the non-display area NA, or may be formed in a plurality of areas of the non-display area NA.

A dam DAM surrounding the display area AA is formed in the non-display area NA. When the thin film transistor or the organic light emitting layer of the display apparatus 100 is exposed to external impurities such as air or moisture, the thin film transistor or the organic light emitting layer is deteriorated and the display apparatus 100 is defective. Therefore, an encapsulation layer (not shown) must be formed in the display apparatus 100 to seal the display apparatus 100 from the external environment. As will be explained later, when applying the encapsulation material to form an encapsulation layer, the dam DAM is formed in the non-display area NA to block the flow of the encapsulation material, thereby preventing the encapsulation material from flowing to the outside of the display apparatus 100.

In the drawing, only one dam DAM is arranged, but multiple dams DAM may be arranged to reliably prevent the sealing material from flowing out of the display apparatus 100. The dam DAM is arranged closer to the display area AA than the gate driving unit GIP, but is not limited thereto.

As will be described in detail later, the display apparatus 100 according to the present disclosure is a flexible display apparatus. For example, the display apparatus 100 according to the present disclosure may be a foldable display apparatus, a bendable display apparatus, or a stretchable display apparatus, but is not limited thereto.

The substrate of the flexible display apparatus is mainly made of a plastic material such as polyimide. Since the organic material such as the ployimide is vulnerable to moisture permeation, the flexible display apparatus should be mainly made of two plastic substrates and a moisture-resistant inorganic layer disposed therebetween.

The inorganic layer is formed in the entire display area AA and non-display area NA of the display apparatus 100, and a pattern structure PAT (also referred to as ‘a pattern unit PAT’) is formed in the inorganic layer 100 of the non-display area NA. The upper and lower plastic substrates are directly contacted to each other through the pattern unit PAT.

In general, when inorganic and organic materials are bonded, the bonding strength of the inorganic and organic materials is reduced due to the difference in the interface characteristics of the two materials. Since the two plastic substrates disposed with the inorganic layer therebetween are directly contacted to each other through the pattern unit PAT, the bonding strength of the two plastic substrates is improved to prevent the separation of the two plastic substrates.

As will be described in detail later, a number of through holes are formed in the pattern unit PAT so that the upper and lower plastic substrates are directly contacted to each other. The through holes can be formed in various shapes.

In the drawing, the pattern unit PAT is arranged outside the dam DAM of the non-display area NA, but is not limited thereto. Further, the pattern unit PAT is arranged in an area excluding the gate driving unit GIP, but is not limited thereto. And, in the drawing, the pattern unit PAT is formed to surround the display area AA, but the pattern unit PAT may be formed only in a predetermined area as needed.

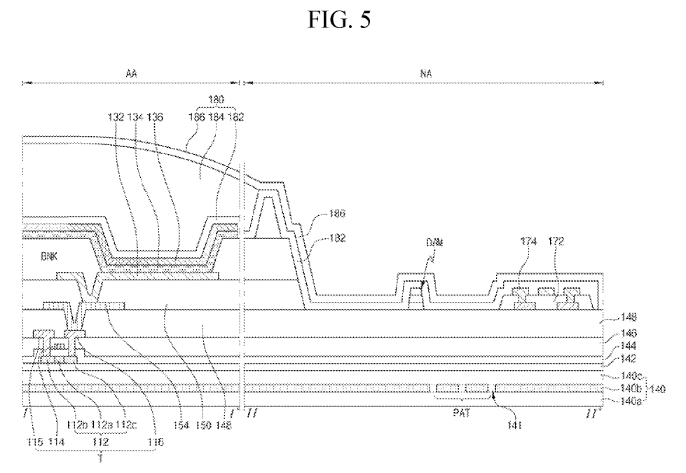

FIG. 5 is a cross-sectional view of the display apparatus 100 according to the first embodiment of the present disclosure, taken along line I-I′ of FIG. 4.

As shown in FIG. 5, the substrate 140 includes the display area AA and the non-display area NA. The substrate 140 may made of the flexible material. For example, the substrate 140 may include a plurality of base layers 140a and 140c and an intermediate layer 140b between the base layers 140a and 140c. In the drawing, the substrate 140 includes two base layers 140a and 140c and one intermediate layer 140b, but may include of three or more base layers and two or more intermediate layers.

The base layer 140a and 140c may be made of a plastic material. For example, the plastic material may include a polyimide, a polymethylmethacrylate, a polyethylene tereththalate, a Polyethersulfone, and a Polycarbonate.

The intermediate layer 140b may be made of the inorganic material. For example, the intermediate layer 140b may be made of SiOx or SiNx, but is not limited thereto.

Since the substrate 140 includes the base layer 140a and 140c made of the plastic material and the intermediate layer 140b made of then inorganic material, moisture penetration into the inside of the display apparatus 100 from the outside can be blocked.

In general, the organic materials such as plastic are vulnerable to moisture penetration, while the inorganic materials block moisture penetration. Therefore, in the present disclosure, by disposing the intermediate layer 140b made of the inorganic material between base layers 140a and 140c made of the plastic material, moisture penetration into the inside of the display apparatus 100 is prevented.

A buffer layer 142 is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer in each sub-pixel SP1, and SP2. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be formed in the entire area of the substrate 140 or formed only in a part area of the substrate 140. The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A first planarization layer 148 is formed on the substrate where the thin film transistor is disposed. The first planarization layer 148 may be formed of the organic material such as photoacrylic. But it is not limited thereto. The first planarization layer 148 may include a plurality of layers including the inorganic layer and the organic layer.

A connection pattern 154 is disposed on the first planarization layer 148 and is electrically connected to the drain electrode 116 of the thin film transistor T through a contact hole formed in the first planarization layer 148. The connection pattern 154 may be made of metal.

A second planarization layer 150 is formed on the first planarization layer 148 on which a connection pattern 154 is formed. The second planarization layer 150 may be formed of the organic material such as photo acrylic, but it is not limited thereto. The second planarization layer 150 may include a plurality of layers including the inorganic layer and the organic layer. The second planarization layer 150 may be made of the same material as the first planarization layer 148, but may also be made of a different material.

In the present disclosure, by forming the planarization layer in a two-layer structure 148 and 150, various electrodes and signal lines can be formed between the first and second planarization layers 148 and 150. Accordingly, since the electrodes can be arranged vertically, the area due to the electrodes and signal line in the sub-pixel can be reduced, and as a result the area of the sub-pixel can be reduced for a high-resolution display apparatus 100.

A light emitting device D is disposed on the second planarization layer 158 in the display area AA. The light emitting device D includes a first electrode 132, an organic layer 134, and a second electrode 136.

The first electrode 132 is disposed on the second planarization layer 150 and electrically connected to the drain electrode 116 of the thin film transistor through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

A bank layer BNK is formed at the boundary between the sub-pixels on the second planarization layer 150. The bank layer 152 may be a barrier wall to define sub-pixels. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

The light emitting layer 134 may be formed on the upper surface of the first electrode 132 of the display area AA, the inclined surface of the bank layer BNK, and a portion of the upper surface of the bank layer BNK and then may extend to the non-display area NA.

The light emitting layer 134 may be formed in the R, G, and B pixels and may include an R-emitting layer that emits red light, a G-emitting layer that emits green light, and a B-emitting layer that emits blue light. For example, the light emitting layer 134 may include an organic light emitting layer, an inorganic light emitting layer, a nano-sized material layer, a quantum dot, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the single layer or the multi layers made of the metal or the alloy thereof. Further, the second electrode 136 may be made of the transparent metal oxide material such as ITO or IZO, but is not limited thereto.

When the display apparatus 100 is the top emission type, the second electrode 136 may be made of the half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 may be the reflective electrode made of the opaque conductive material. For example, the second electrode 188 may be made of at least one or more of silver (Ag), aluminum (Al), gold (Au), molybdenum (Mo), tungsten (W), chromium (Cr), or alloys thereof.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 180 is formed on the light emitting device D in the display area AA and the non-display area to seal the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 160 blocks impurities such as the oxygen and the moisture from the outside to prevent defects of the light emitting device D and various electrodes.

The encapsulation layer 180 may be formed of a first encapsulation layers 182, a second encapsulation layer 184, and a third encapsulation layer 186, but is not limited thereto. The encapsulation layer 180 may be formed of two layers or four or more layers.

The first encapsulation layer 182 and the third encapsulation layer 186 may be made of the single layer or the multiple layers including the inorganic materials such as SiOx, SiON, SiNx, etc., and may further include the organic materials between the inorganic materials such as SiOx, SiON, SiNx, etc., but are not limited thereto. The second encapsulation layer 184 may be made of epoxy resin.

Not shown in figure, a touch member may be disposed on the encapsulating layer 180. The touch member can detect external touch information using the user’s finger or a touch pen.

A dam DAM is formed outside the non-display area NA. Since the organic material forming the second encapsulation layer 184 has fluidity, the organic material may flow out to the outside of the substrate 140 by the fluidity when the second encapsulation layer 184 is formed. Since the dam DAM is formed to surround the display area NA, the organic materials flowing out of the substrate 140 may be contained by the dam DAM when the second encapsulation layer 184 is formed. Therefore, the organic material does not flow out of the substrate 140. In the figure, although only one dam DAM is shown, the multiple dams DAM may be disposed.

The dam DAM may be formed of the multiple layers. For example, the dam DAM may be formed of layers of the same material as the first planarization layer 148, the second planarization layer 150, and the bank layer BNK. For example, the dam DAM may include black pigment. However, the dam DAM of the present disclosure is not limited thereto and may be formed of the single layer or two layers.

A gate driving unit GIP may be disposed in the outside of the dam DAM of the non-display area NA. The gate driving unit GIP may be made of a plurality of thin film transistors 172 and 174 and a plurality of signal lines (not shown in the drawing). The thin film transistors 172 and 174 may be disposed on the first planarization layer 148 or the second planarization layer 150.

A pattern unit PAT is formed between the dam DAM and the gate driving unit GIP in the non-display area NA. The pattern unit PAT may be formed of a plurality of through holes 141 formed in the intermediate layer 140b of the substrate 140. The first and second base layers 140a and 140c disposed above and below the intermediate layer 140b are connected to each other by the through holes 141 to contact directly the first and second base layers 140 and 140c to each other for the following reasons.

The first and second base layers 140a and 140c of the substrate 140 are made of the plastic material, and the intermediate layer 140b is made of the inorganic material. Accordingly, the first and second base layers 140a and 140c and the intermediate layer 140b are made of different materials, so the adhesive strength between the first base layer 140a and the intermediate layer 140b and between the second base layer 140c and the intermediate layer 140b is reduced. As a result, when an external force is applied to the display apparatus 100, the first and second base layers 140a and 140c may be separated from the intermediate layer 140b.

In particular, the display apparatus 100 is fabricated by forming a plurality of unit panels on the substrate and then cutting the substrate to separate the plurality of unit panels. When the substrate is cut, stress is applied to the outside of the display apparatus 100. Due to the weak adhesive force between the first base layer 140a and the intermediate layer 140b and between the second base layer 140c and the intermediate layer 140b, the first and second base layers 140a and 140c may be separated because of the stress when the substrate is cut.

In the present disclosure, the first and second base layers 140a and 140c are directly contacted to each other in the pattern unit PAT. At this time, since the first and second base layers 140a and 140c are made of the same plastic material, the interface characteristics are the same. Therefore, by the first and second base layers 140a and 140c contacted directly to each other, the bonding force of the first and second base layers 140a and 140c increases more than the bonding force in other areas, so that the separation the substrate 140 in the non-display area NA of the display apparatus 100 can be prevented.

The through hole 141 of the pattern unit PAT can be formed in various shapes.

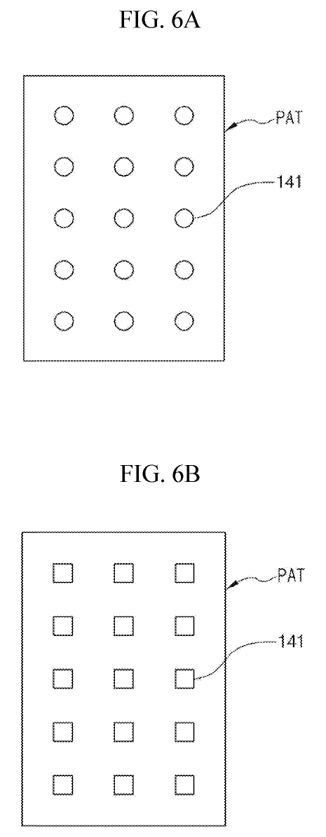

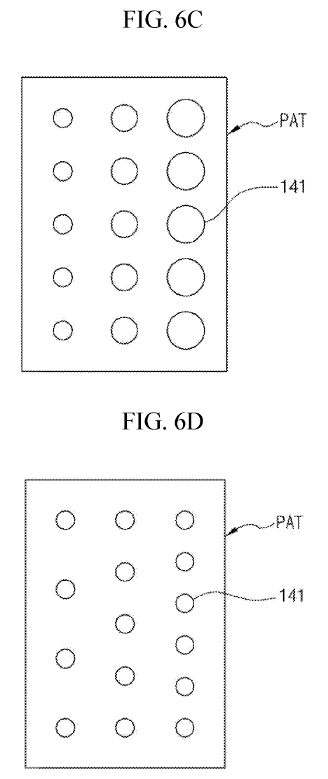

As shown in FIGS. 6A and 6B, the through hole 141 may be formed in a circular shape or a rectangular shape, but is not limited thereto. The through hole 141 may be formed in various shapes such as a triangular shape, a pentagonal shape, a diamond shape, etc. The through hole 141 may be formed with a uniform area and a uniform pitch in the entire pattern portion PAT, but may be formed with different areas and pitches.

When the substrate is cut into unit panels, the stress at the edge of the display apparatus 100 is the strongest and decreases as it goes inward. Accordingly, the substrate 140 is most easily separated at the edge of the display apparatus 100 and the degree of separation decreases as it goes inward.

Considering this, in the present disclosure, as shown in FIG. 6C, the area of the through hole 141 is increased from the inner side to the edge of the display apparatus 100, so that the bonding force of the first and second base layers 140a and 140c is increased from the inner side to the edge of the display apparatus 100, thereby preventing the separation of the first and second base layers 140a and 140c.

Further, as shown in FIG. 6D, the density of the through holes 141 is increased from the inner side to the edge of the display apparatus 100, so that the bonding force of the first and second base layers 140a and 140c is increased from the inner side to the edge of the display apparatus 100, thereby preventing separation of the first and second base layers 140a and 140c.

Further, the edge of the display apparatus 100 may be an area vulnerable to external impact. For example, the stress at the edge of the display apparatus 100 may be the strongest and the stress may decrease toward the inside. Therefore, as shown in FIGS. 6A to 6D, if the through holes 141 are formed in the substrate 140, the crack transmitted through the intermediate layer 140b between the base layers 140a and 140c can be prevented. In particular, as shown in FIGS. 6C and 6D, by increasing the area of the through holes 141 from the inner side of the display apparatus 100 to the edge or by increasing the density of the through holes 141 from the inner side of the apparatus 100 to the edge, the crack transmitted into the display apparatus 100 through the intermediate layer 140b between the base layers 140a and 140c can be more effectively prevented.

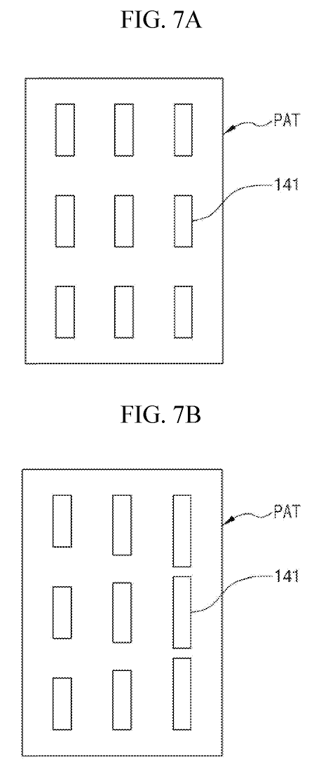

As shown in FIG. 7A, the through hole 141 may be formed in a slit shape. At this time, the slit may be formed uniformly in the entire area of the pattern portion PAT, and the length of the slit may be increased from the inner side of the display apparatus 100 to the edge as shown in FIG. 7B. Although not shown in the drawing, the width of the slit may be increased from the inner side to the edge of the display apparatus 100, so that the bonding force of the first and second base layers 140a and 140c may be increased from the inner side to the edge of the display apparatus 100.

As described above, in the present disclosure, since the substrate 140 includes two base layers 140a and 140c and the intermediate layer 140b therebetween, the moisture can be prevented from penetrating into the display apparatus 100 from the outside.

Further, in the present disclosure, the through hole 141 for connecting the first and second base layers 140a and 140c is formed in the intermediate layer 140b made of the inorganic material, so that the first and second base layers 140a and 140c are directly contact to each other, so that the bonding strength of the first and second base layers 140a and 140c is increased and thus the first and second base layers 140a and 140c are not separated.

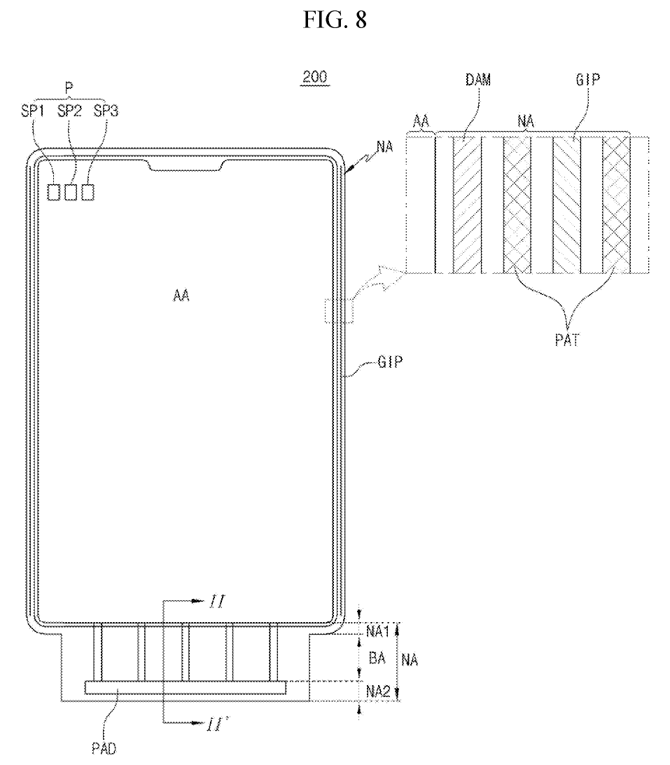

FIG. 8 is the plan view schematically showing the display apparatus 200 according to a second embodiment of the present disclosure. The display apparatus 200 of this embodiment is the display apparatus 200 in which some areas are bent.

As shown in FIG. 8, the display apparatus 200 of this embodiment includes the display area AA where the image is displayed and the non-display area NA surrounding the display area AA.

The non-display area NA is the area where the images are not displayed and where the various signal lines and the driving circuits for driving multiple sub-pixels SP1, SP2, and SP3 of the display area AA are disposed.

The non-display area NA may be formed to surround the display area AA at the outer edge of the display area AA. At this time, the non-display area NA at the bottom of the display area AA may include first and second non-display areas NA1 and NA2 and a bending area BA. The bending area BA is an area that is bent (or curved). As the bending area BA is bent, the first non-display area NA1 is positioned on the front side of the display apparatus 200 and the second non-display area NA2 is positioned on the rear side of the display apparatus 200.

The first non-display area NA1 may be the area where the various types of signal lines are disposed. Although not shown in the drawing, for example, a part of a low-potential voltage line VSS and a part of a high-potential voltage line VDD may be disposed in the first non-display area NA1.

The second non-display area NA2 may be a pad area. A pad PAD is disposed in the second non-display area NA2. Although not shown in the drawing, a flexible circuit board such as an FPC (Flexible Printed Circuit board) or COF (Chip On Film) may be attached to the pad PAD to supply the external signal can be supplied into the inside of the display apparatus 200.

The dam DAM can be disposed in the non-display area NA. The dam DAM is formed in the non-display area NA in a closed curve shape to surround the display area AA. The pattern unit PAT is formed in the non-display area NA. The pattern unit PAT in the non-display area NA at the bottom of the display area AA is formed in the first non-display area NA1, the bending area BA, and the second non-display area NA2.

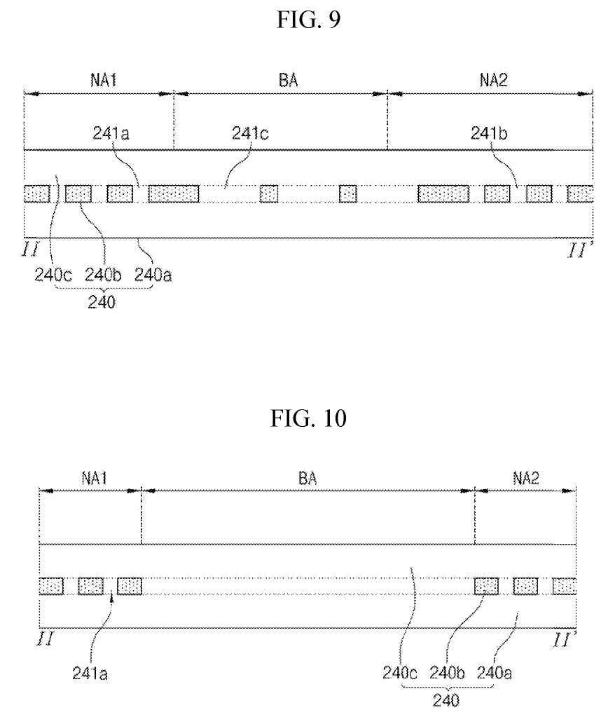

FIG. 9 is the cross-sectional view taken along line II-II′ of FIG. 8, which shows the structure of the non-display area NA at the bottom of the display area AA. At this time, only the lower portion of the substrate 240 is shown in the drawing for convenience of explanation. Since the structure of the upper portion of the substrate 240 is the same as that of the display apparatus 100 according to the first embodiment shown in FIG. 5, the drawing and explanation for the upper portion of the substrate 240 are omitted.

As shown in FIG. 9, the substrate 240 may be formed of a plurality of base layers 240a and 240c and the intermediate layer 240b therebetween. In the drawing, the substrate 240 is formed of two base layers 240a and 240c and one intermediate layer 240b, but may be formed three or more base layers and two or more intermediate layers.

The first and second base layers 240a and 240c may be made of the plastic material. For example, the first and second base layers 240a and 240c may be formed of at least one of polyimide, polymethylmethacrylate, polyethylene terephthalate, polyethersulfone, and polycarbonate, but is not limited thereto.

The intermediate layer 240b may be made of the inorganic material. For example, the intermediate layer 240b may be made of SiOx or SiNx, but is not limited thereto.

Through holes 241a, 241b, and 241c are formed in the intermediate layer 240b so that the first and second base layers 240a and 240c are directly contacted to each other through the through holes 241a, 241b, and 241c, and thus the bonding strength of the first and second base layers 240a and 240c is improved.

At this time, the area of the through holes 241a, 241b, and 241c is dependent upon the position thereof. When the bending area BA of the display apparatus 200 is bent, the stress is applied to the display apparatus 200, and the intensity of the stress is dependent upon the position thereof. For example, a relatively strong stress may be applied to the bending area BA, and a relatively weak stress may be applied to the first non-display area NA1 and the second non-display area NA2.

The through holes 241a, 241b, and 241c enhance the bonding strength of the first and second base layers 240a and 240c to prevent separation of the first and second base layers 240a and 240c by the stress. By increasing the area of the through hole 241b formed in the bending area BA where the relatively strong stress is applied, the bonding strength of the first and second base layers 240a and 240c in this area is strongest and thus the separation of the first and second base layers 240a and 240c can be prevented.

In the first non-display area NA1 and the second non-display area NA2 where relatively weak stress is applied, even if the area of the through hole 241a and 241c is small, the separation of the first and second base layers 240a and 240c in these areas can be prevented.

The intensity of the stress applied to the first non-display area NA1 may be greater than the intensity of the stress applied to the second non-display area NA2, because of the bending of the bending area BA. In this case, the area of the through hole 241a formed in the first non-display area NA1 is larger than that of the through hole 241c formed in the first non-display area NA2, so that the separation of the first and second base layers 240a and 240c caused by the stress may be prevented.

Further, the separation of the through holes 241a, 241b, and 241c can be prevented by controlling the intensity of the applied stress in accordance with the intensity of the stress.

FIG. 10 is a view showing another structure of the non-display area NA at the bottom of the display area AA in the substrate 240 of the display apparatus 200 according to a second embodiment of the present disclosure.

As shown in FIG. 10, the substrate 240 of the first and second non-display areas NA1 and NA2 includes a plurality of base layers 240a and 240c and the intermediate layer 240b therebetween. In the drawing, although the substrate (240) of the first and second non-display areas NA1 and NA2 includes two base layers 240a and 240c and one intermediate layer 240b, but may include three or more base layers and two or more intermediate layers.

The first and second base layers 240a and 240c may be made of the plastic material. For example, the first and second base layers 240a and 240c may be formed of at least one of polyimide, polymethylmethacrylate, polyethylene terephthalate, polyethersulfone, and polycarbonate, but is not limited thereto.

The intermediate layer 240b may be made of the inorganic material. For example, the intermediate layer 240b may be made of SiOx or SiNx, but is not limited thereto.

Through holes 241a and 241b are formed in the intermediate layer 240b so that the first and second base layers 240a and 240c are directly contacted to each other through the through holes 241a and 241bc, and thus the bonding strength of the first and second base layers 240a and 240c is improved.

In the drawing, the area and density of the through holes 241a and 241b formed in the first and second non-display areas NA1 and NA2 are the same, but the area and density may be varied in dependent upon the intensity of the stress applied to the substrate 240. For example, when the intensity of stress applied to the first non-display area NA1 is greater, the area or density of the through holes 241a formed in the first non-display area NA1 may be greater than the area or density of the through holes 241b formed in the second non-display area NA2.

The intermediate layer is not formed in the bending area BA. When the substrate 240 is bent, the maximum stress is applied to the bending area BA. Therefore, by removing the intermediate layer in the bending area, the first and second base layers 240a and 240c are totally contacted in the bending area BA so that the separation of the first and second base layers 240a and 240c may be prevented in the bending area BA.

As described above, in the display apparatus of this embodiment, the intermediate layer is deleted or the area or the density of the through holes is maximized in the region where the substrate 240 is deformed, such as the region where the substrate 240 is bent, the region where the substrate 240 is folded, the region where the substrate 240 is stretched, or the region where the substrate 240 is folded, etc., to maximize the bonding force between the plastic base layers in this region. Therefore, it is possible to prevent the separation of the plastic base layers in the region where the substrate 240 is deformed.

In the display apparatus of this embodiment, further, the intermediate layer is deleted or the area or the density of the through holes is maximized in the region where the substrate 240 is deformed, such as the region where the substrate 240 is bent, the region where the substrate 240 is folded, the region where the substrate 240 is stretched, or the region where the substrate 240 is folded, etc., to prevent the damage of the display apparatus 200 caused by the crack propagating through the intermediate layer.

The pattern unit, e.g., the through hole, may be formed in the entire area where the substrate 240 is deformed, but may be formed only in a specific area. For example, when the display area is folded, the through hole may be formed only in the portion where the light emitting device is disposed in the folding area, but is not limited thereto.

Further, since the light emitting device is disposed in the display area and the image is displayed in the folding area where the light emitting device is disposed, the light emitting device and the pattern unit may be overlapped in at least a part of the area.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area having a plurality of sub pixels and a non-display area outside the display area; and
a transistor and a light emitting device disposed respectively in each of the plurality of sub pixels,
wherein the substrate includes a plurality of base layers and at least one intermediate layer therebetween, and
wherein a pattern structure is formed in the intermediate layer to contact directly the base layers disposed above and below the intermediate layer.

2. The display apparatus of claim 1, wherein the base layer is formed of a plastic material.

3. The display apparatus of claim 1, wherein the intermediate layer is formed of an inorganic material.

4. The display apparatus of claim 1, wherein the pattern structure includes a plurality of through holes formed in the intermediate layer.

5. The display apparatus of claim 4, wherein at least one through hole of the plurality of through holes is formed in a circular shape or a polygon shape.

6. The display apparatus of claim 5, wherein an area of at least one through hole of the plurality of through holes increases toward an outer edge of the non-display area.

7. The display apparatus of claim 5, wherein a density of at least one through hole of the plurality of through holes increases toward an outer edge of the non-display area.

8. The display apparatus of claim 4, wherein at least one through hole of the plurality of through holes is formed in a slit shape.

9. The display apparatus of claim 8, wherein a width or a length of at least one through hole of the plurality of through holes increases toward an outer edge of the non-display area.

10. The display apparatus of claim 8, wherein a deformation area is formed in the non-display area of the substrate.

11. The display apparatus of claim 10, wherein the deformation area includes a bending area, a folding area, a stretching area, and a curved area.

12. The display apparatus of claim 11, wherein the folding area overlaps the display area.

13. The display apparatus of claim 12, wherein the pattern structure of the folding area overlaps the light emitting device.

14. The display apparatus of claim 10, wherein the intermediate layer in the deformation area is deleted.

15. The display apparatus of claim 10, wherein the size of at least one through hole of the plurality of through holes in the deformation area is larger than a size of at least one through hole of the plurality of through holes in another area of the substrate.

16. A substrate for a display apparatus, the substrate comprising:
a plurality of base layers;
at least one intermediate layer between the base layers; and
a plurality of through holes formed in the intermediate layer to contact directly the base layers therethrough.

17. The substrate of claim 16, wherein the base layer is formed of a plastic material and the intermediate layer is formed of an inorganic material.

18. The substrate of claim 16,
wherein the substrate includes a plurality of areas, and
wherein a size or a density of the through holes formed in the plurality of areas depends on a stress distribution within the substrate.

19. The substrate of claim 16, wherein a deformation area is formed and the intermediate layer is deleted in the deformation area.

20. The substrate of claim 18, wherein a size or a density of at least one through hole of the plurality of through holes formed in the deformation area is larger than that in another area of the substrate having a lower stress distribution.
